(19) United States
(12) Patent Application Publication
(10) Pub. No.: US 2011/0260193 A1
(43) Pub. Date: Oct. 27, 2011

(54) Method for Producing a Luminescence Conversion Element, Luminescence Conversion Element and Optoelectronic Component

(75) Inventor: Gertrud Kraeuter, Regensburg (DE)

(73) Assignee: OSRAM Opto Semiconductors GmbH, Regensburg (DE)

(21) Appl. No.: 13/124,744

(22) PCT Filed: Sep. 29, 2009
(86) PCT No.: PCT/DE2009/001378

§ 371 Date: Jul. 13, 2011

(30) Foreign Application Priority Data
Oct. 22, 2008 (DE) 10 2008 052 751.3

(51) Int. Cl. H01L 33/50; B29D 11/00; F21V 9/16; G02B 1/00

(52) U.S. Cl. 257/98; 264/1.21; 362/84; 257/E33.061

(57) ABSTRACT

A method is provided for producing a luminescence conversion element (4), in particular for an optoelectronic component. In the method a raw material (1) is provided, which is intended for further processing to yield the ceramic material and which contains luminescent material particles and a binder material. A blank is molded by injecting the raw material (1) into a closed mold (3). The blank is released from the mold (3). The binder material is removed from the blank. The blank is sintered to yield the luminescence conversion element (4), wherein the luminescent material particles are bonded together and/or with further particles of the raw material to yield the ceramic material.

A luminescence conversion element and an optoelectronic component are additionally provided.

This patent application claims priority from German patent application 102008052751.3, whose disclosure content is hereby included by reference.

The present application relates to a method of producing a luminescence conversion element, to a luminescence conversion element and to an optoelectronic component.

Optoelectronic components with a luminescence conversion element conventionally comprise a radiation-emitting semiconductor chip. The luminescence conversion element contains at least one luminescent material. The radiation-emitting semiconductor chip emits electromagnetic radiation of a first wavelength range when the component is in operation. The luminescent material converts at least part of this radiation into electromagnetic radiation of a second wavelength range, which is different from the first wavelength range. Such components are known, for example, from publication WO 97/50132.

In such components the luminescence conversion element conventionally contains particles of the luminescent material in a matrix of epoxy resin or of a silicone material. The thermal conductivity of the epoxy resin or silicone matrix material is often insufficient satisfactorily to dissipate heat losses from the semiconductor chip of the component.

It is an object of the present application to provide a luminescence conversion element with good thermal conductivity, an improved optoelectronic component and a versatile method of producing a luminescence conversion element.

This object is achieved by a method of producing a luminescence conversion element, by a luminescence conversion element and by an optoelectronic component according to the independent claims.

Advantageous configurations and further developments of the method, the luminescence conversion element and the component are in each case indicated in the dependent claims. The disclosure content of the claims is hereby included explicitly in the description by reference.

A luminescence conversion element is provided which comprises a ceramic material. The luminescence conversion element conveniently mostly comprises the ceramic material. “Mostly” means that the ceramic material takes up more than 50%, in particular more than 75%, preferably more than 90% of the volume of the luminescence conversion element. The luminescence conversion element particularly preferably consists of the ceramic material. The luminescence conversion element is provided in particular for an optoelectronic component.

The ceramic material contains luminescent material particles, which are bonded together and/or with further particles to yield the ceramic material. The bonds of the luminescent material particles with each other and/or to further particles of the ceramic material at least in part formed by so-called “sinter necks”. Alternatively or in addition, grain boundaries may also be formed between neighbouring particles, in particular particles adjoining one another over a large area.

The ceramic material may consist of the luminescent material particles, for example. Alternatively, in addition to the luminescent material particles it may contain further particles, which in particular do not exhibit any wavelength-converting properties. The further particles for example comprise at least one of the following materials or consist of at least one of the following materials: aluminum oxide, aluminum nitride, boron nitride, titanium dioxide, zirconium dioxide, silicon dioxide.

In one advantageous configuration the luminescent material particles have a median grain diameter of less than or equal to 10 μm. In another configuration they have a median grain diameter of less than or equal to 5 μm, in particular of less than or equal to 1 μm. Such luminescent material particles are particularly advantageous for wavelength conversion of the electromagnetic radiation emitted by a semiconductor chip.

In one configuration, the further particles have a median grain diameter of less than or equal to 1 μm, in particular of less than or equal to 500 nm. The median grain diameter of the further particles is preferably greater than or equal to 300 nm. With further particles having such a grain diameter, particularly good diffusion properties may for example be achieved in the luminescence conversion element.

The term “grain diameter” in this case denotes the diameter of the smallest sphere which completely contains the luminescent material particle or the further particle. “Median grain diameter” is here understood to mean the median of the thus defined grain diameter, relative to the number of particles. In other words, half the luminescent material particles/further particles have a grain diameter which is greater than the median grain diameter and half of the luminescent material particles/further particles have a grain diameter which is smaller than the median grain diameter. The median grain diameter may for example be determined by means of a photomicrograph of a section through the luminescence conversion element. The median grain diameter is also designated as “d₅₀”.

In one configuration the outer surface of the luminescence conversion element comprises a concavely curved subregion and/or a convexly curved subregion. In particular, at least one subregion of the luminescence conversion element takes the form of a lens, for example a convex lens or concave lens, in particular a plane convex lens or plane concave lens.

In another configuration the luminescence conversion element exhibits the shape of a dome or a cap with a lid portion and at least one side wall. The side wall or a plurality of side walls laterally surround the lid portion or a central region of the lid portion, such that the lid portion and the side wall/side walls define an internal space. In particular, the main plane of extension of the lid portion extends obliquely of or perpendicularly to the main plane(s) of extension of the side wall or the side walls. In one configuration the lid portion and the at least one side wall are constructed in one piece. The internal space is in particular open on the side opposite from the lid portion.

An optoelectronic component is additionally provided. The component comprises a luminescence conversion element, which consists of a ceramic material. The luminescence conversion element is constructed in particular according to one of the above-described configurations. The optoelectronic component further comprises a radiation-emitting semiconductor chip.

The semiconductor chip is provided to emit electromagnetic radiation of a first wavelength range. The luminescence conversion element is provided to convert at least part of the electromagnetic radiation emitted by the semiconductor chip in the first wavelength range into a second wavelength range different at least in part from the first.

If the luminescence conversion element exhibits the shape of a cap with a lid portion and at least one side wall, in one configuration of the component the semiconductor chip is arranged at least partially in the cap. In particular, the radiation-emitting semiconductor chip is arranged wholly or partially in the internal space of the cap. The dimensions of the internal space are selected for example such that said internal space is suitable solely for accommodating the semiconductor chip. The internal space is in this case at most slightly larger than the semiconductor chip. In an alternative configuration the luminescence conversion element is spaced from the semiconductor chip. For example, it is attached to a housing of the component.

A method of producing the luminescence conversion element is also indicated. The method comprises the following steps, preferably in the stated sequence:

a) providing a raw material, which is intended for further processing to yield a ceramic material and which contains luminescent material particles and a binder material,
b) molding a blank by injecting the raw material into a closed mold,
c) releasing the blank from the mold,
d) removing the binder material from the blank, and
e) sintering the blank to yield the luminescence conversion element, wherein the luminescent material particles are bonded together and/or with further particles of the raw material to yield the ceramic materials.

A closed mold is understood in the present connection in particular to mean a mold which, apart from an injection orifice and optionally vent openings, is completely closed. The mold preferably consists of at least two portions which are configured to be assembled into the mold. The raw material is expediently injected when the portions are in the assembled state. Release of the blank from the mold expediently includes opening of the mold, which for example comprises removal of at least a first portion. In particular, after removal of at least the first portion, the blank is taken out of the other or one of the other portions.

The mold expediently encloses an internal space, which exhibits the shape of the luminescence conversion element to be produced. Shaping of the blank advantageously proceeds by injection into the mold, which has a correspondingly shaped internal space. For instance, luminescence conversion elements of the most varied shapes may be simply produced using the method.

For example, a blank is molded by injection of the raw material into the correspondingly shaped internal space of the mold, which blank takes the form of a dome or a cap with a lid portion and at least one side wall. In another configuration the mold is designed such that, by injecting the raw material, a blank is molded whose outer surface comprises a convexly curved subregion and/or a concavely curved subregion. In this way, a luminescence conversion element is produced which comprises a convex or concave lens, for example a plane convex or plane concave lens.

In a further configuration a raw material is provided which contains additional particles without wavelength-converting properties, in addition to the luminescent material particles. The additional particles may for example be aluminum oxide particles, aluminum nitride particles and/or boron nitride particles. The additional particles expediently remain as a constituent of the ceramic material in the finished luminescence conversion element. In particular, they bind together and/or with the luminescent material particles to form the ceramic material.

In one configuration of the method the raw material comprises luminescent material particles which exhibit a median grain diameter of less than or equal to 5 μm and in particular of less than or equal to 1 μm. In one further development, the median grain diameter is greater than or equal to 500 nm. In another further development the luminescent material particles bind together and/or with further particles of the raw material during sintering to yield particles with a median grain diameter of greater than or equal to 1 μm, in particular of greater than or equal to 5 μm.

In a further configuration the additional particles have a median grain diameter of less than or equal to 1 μm, in particular of less than or equal to 500 nm. In a further development, the median grain diameter of the additional particles, which do not have any wavelength-converting properties, is greater than or equal to 200 nm.

In a convenient configuration of the method the binder material contains an acrylate, a polyolefin, a polyol and/or silicone or consists of at least one of these materials. Such binder materials are suitable for being removed from the blank by means of a solvent, by means of catalytic decomposition and/or by means of thermal decomposition. When removing the binder material from the blank, the binder material is preferably removed completely from the blank. However, it is also possible for residues of the binder material to remain in the blank.

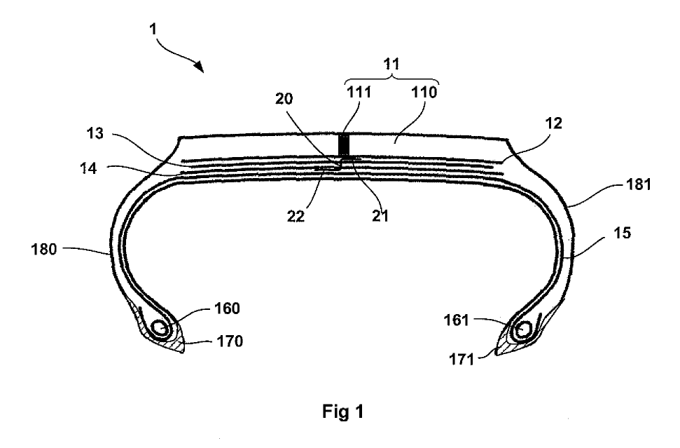

Further advantages, advantageous configurations and further developments of the method, the luminescence conversion element and the component are revealed by the following exemplary embodiments described in conjunction with FIGS. 1 to 4, in which:

FIG. 1 shows a method of producing a luminescence conversion element according to an exemplary embodiment in a schematic sectional representation of one stage of the method,

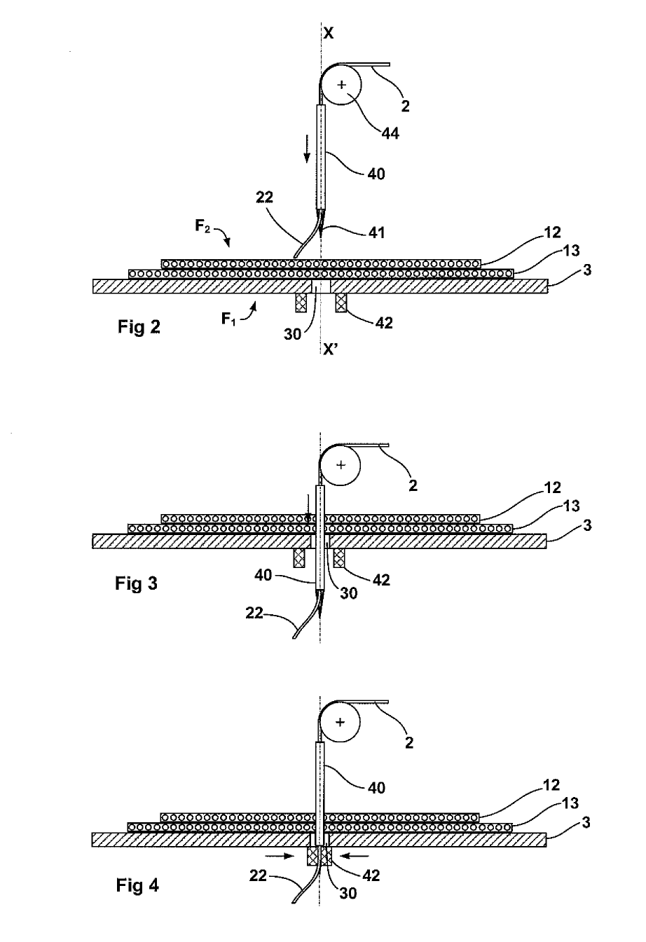

FIG. 2 is a schematic perspective representation of the luminescence conversion element produced by the method of FIG. 1,

FIG. 3 is a schematic sectional representation of a luminescence conversion element according to a further exemplary embodiment, and

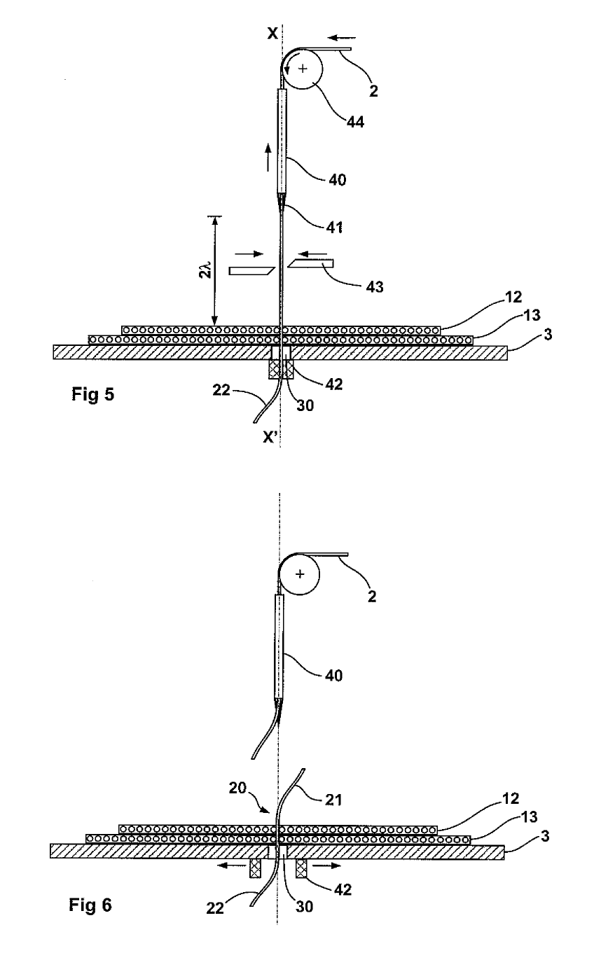

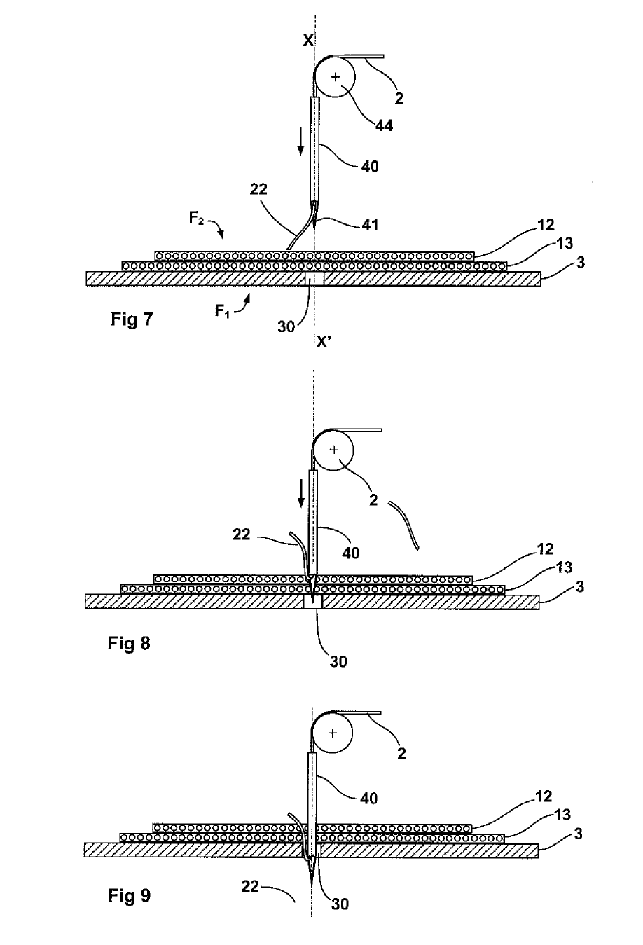

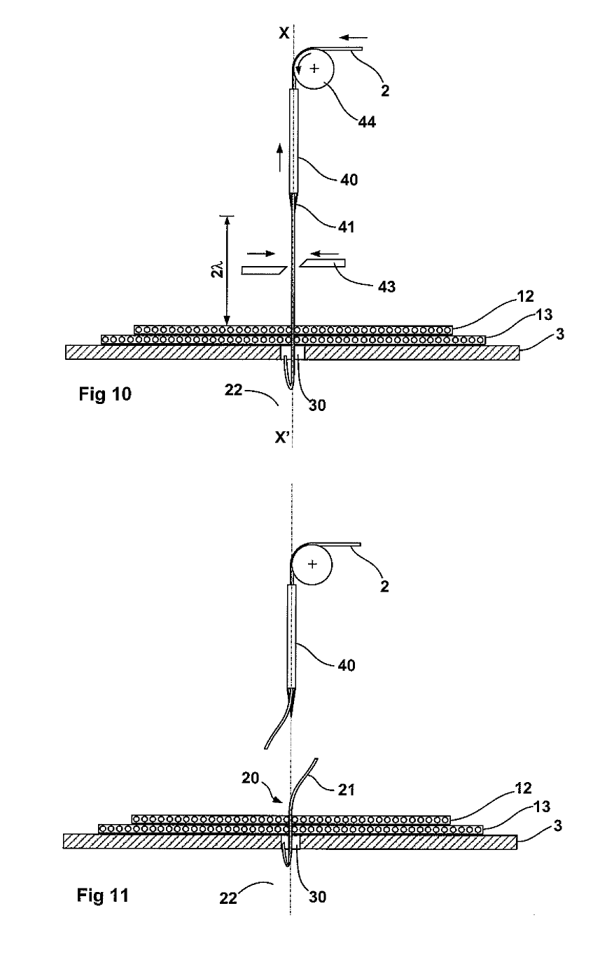

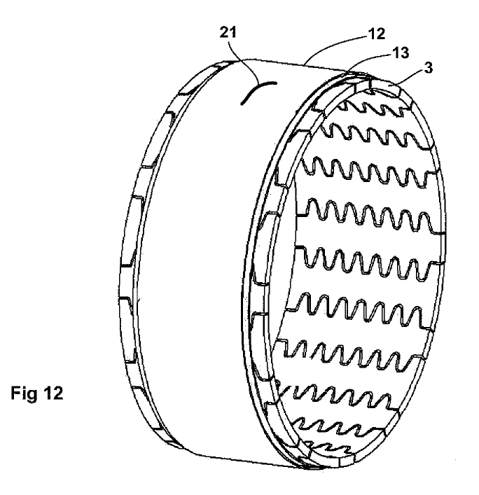

FIG. 4 is a schematic perspective representation of an optoelectronic component with the luminescence conversion element according to the exemplary embodiment of FIG. 2.

In the exemplary embodiments and figures, similar or similarly acting components are in each case provided with the same reference numerals. The figures and the elements illustrated in the figures are not to be regarded as being to scale. Rather, individual elements may be illustrated on an exaggeratedly large scale for greater ease of depiction and/or better comprehension.

FIG. 1 is a schematic sectional representation of one stage of a method of producing a luminescence conversion element.

In the method a raw material 1 is provided. The raw material consists in this case of luminescent material particles, which are mixed with a binder material such as an acrylate or silicone. The raw material is provided for example in the form of granules.

The proportion of luminescent material particles in the volume of the raw material 1 amounts for example to 50% or more. If the raw material contains additional particles, for example aluminium oxide particles or aluminium nitride particles, the proportion of luminescent material particles and additional particles together amounts for example to 50% or more, in particular 70% or more, of the volume of the raw material 1.

The raw material 1 provided is conveyed by means of a mechanism 2 to a mold 3. The raw material 1 is heated in the process, such that the binder material melts and the raw material makes a transition into a fluid state. The mechanism 2 comprises for example a reservoir for the raw material, a heated tube with a conveying screw and a nozzle facing the mold 3. The raw material 1 is conveyed from the reservoir through the heated tube, in which the binder material is melted, to the nozzle. The raw material is heated for example to a temperature of between 100° C. and 200° C. Preferably, the mold 3 is likewise heated to a temperature of between 100° C. and 200° C.

The fluid raw material 1 is injected by means of the nozzle through an injection duct 300 of the mold 3 into an internal space 30 of the heated mold 3. The injection pressure with which the raw material 1 is injected from the mechanism 2 into the mold 3 amounts for example to between 500 bar and 1000 bar.

The mold 3 is in this case completely closed apart from the injection duct 300. In other words, the internal space 30 of the mold is connected to the surrounding environment of the mold 3 solely by the injection duct 300.

In order, for example, to reduce the risk of pockets of air being included in the internal space 30 of the mold 3 during injection of the raw material 1, in one configuration of the method the internal space may be evacuated prior to injection. In an alternative variant (not shown in FIG. 1) the mold 3 comprises at least one vent duct, through which air or another gas contained in the internal space 30 prior to injection may escape during injection of the raw material 1 into the internal space 30.

Through injection of the raw material, a blank is produced which exhibits the shape of the internal space 30 of the mold 3. The blank is subsequently released from the mold 3. To this end, the portions 31 and 32, of which the mold 3 is composed, are separated from one another, such that the blank is exposed and may be taken out of one of the portions 31 or 32. Prior to release of the blank from the mold 3, it may be expedient to cool the mold 3 with the blank to a lower temperature than that provided for injection, for example to increase the stability of the blank.

The binder material of the raw material 1 is subsequently removed from the blank. For example, it is washed out of the blank using a solvent process.

The blank is subsequently sintered at a high temperature, for example of 1000° C. or more, wherein the luminescent material particles bond together and/or with the additional particles of the raw material to yield the ceramic material.

FIG. 2 is a schematic perspective view of the luminescence conversion element 4 produced by the method by means of the exemplary embodiment of FIG. 1.

In the present exemplary embodiment the luminescence conversion element 4 exhibits the shape of a cap. The cap comprises a lid portion 41 with a central region 400, which is surrounded laterally by four external walls 42. The lid portion 41 and the side walls 42 extending perpendicularly to the lid portion 41 define an internal space of the cap 4.

In the present case the cap 4 comprises a cut-out 43. For example, when the lid portion 41 is viewed in plan view, the cap, which is rectangular or square apart from the cut-out 43, lacks one corner.

The luminescence conversion element 4 may for example comprise a peripheral flash 44 or a plurality of flashes, which is/are caused by production in the two-part mold 3. At the joint between the first portion 31 and the second portion 32 of the mold 3 a small quantity of the raw material 1 may for example arrive between the portions 31 and 32 on injection into the internal chamber 30, whereby a flash or, depending on the composition of the mold, a plurality of flashes 44 may remain on the finished luminescence conversion element 4. Alternatively or in addition, it is also possible, as FIG. 3 shows, for a projection or an indentation 45 to remain at that point of the luminescence conversion element 4 where the raw material is injected through the injection duct 300 of the mold. Any flashes 44 or residues 45 from the injection duct which may be present may however also be removed from the finished luminescence conversion element 4.

FIG. 3 shows a further exemplary embodiment of a luminescence conversion element 4 in schematic cross-section. According to the exemplary embodiment of FIG. 3 and in contrast to the exemplary embodiment of FIG. 2, the luminescence conversion element 4 is molded in the shape not of a cap but of a plate. When viewed in plan view onto the main plane of extension of the plate, a central region 400 takes the form of a plane convex lens 5.

FIG. 4 shows a schematic perspective view of an optoelectronic component with the luminescence conversion element 4 according to the exemplary embodiment of FIG. 2.

The optoelectronic component comprises a lead frame 7. A radiation-emitting semiconductor chip 6 is attached to a first subregion of the lead frame 7. The luminescence conversion element 4 is pulled over the semiconductor chip 6 like a cap. In the present case the semiconductor chip is arranged entirely inside the cap-shaped luminescence conversion element 4 apart from one corner region, which is left exposed by the luminescence conversion element 4 by means of the cut-out 43. In particular, the lid portion 41 of the cap 4, apart from the corner region, covers the major surface of the semiconductor chip 6 remote from the lead frame 7. The side walls 42 of the cap 4 extend laterally around the semiconductor chip 6 and cover the side flanks thereof.

The exposed corner area of the semiconductor chip 6 comprises an electrical land 60, in particular a bond pad, on its surface remote from the lead frame 7. A bonding wire 8 connects the bond pad 60 to a second subregion of the electrical lead frame 7, which is electrically insulated from the first subregion. Advantageously, mounting of the luminescence conversion element 4 provided with the cut-out 43 may take place before or after electrical contacting of the semiconductor chip 6 by means of the bonding wire 8.

In one configuration, the optoelectronic component, which takes the form for example of a luminescent diode component, comprises a reflector trough, which is molded for example from a plastics material, which is injection molded around the lead frame. The reflector trough is here omitted to simplify the illustration.

The description made with reference to exemplary embodiments does not restrict the invention to these embodiments. Rather, the invention encompasses any novel feature and any combination of features, even if this feature or this combination is not itself explicitly indicated in the exemplary embodiments or claims.

1. A method of producing a luminescence conversion element, in particular for an optoelectronic component, comprising the steps of:
a) providing a raw material, which is intended for further processing to yield a ceramic material and which contains luminescent material particles and a binder material;
b) molding a blank by injecting the raw material into a closed mold;
c) releasing the blank from the mold;
d) removing the binder material from the blank; and
e) sintering the blank to yield the luminescence conversion element, wherein the luminescent material particles are bonded together and/or with further particles of the raw material to yield the ceramic material.

2. The method according to claim 1, wherein the mold is designed such that, by injecting the raw material, a blank is molded whose outer surface comprises a convexly curved subregion and/or a concavely curved subregion.

3. The method according to claim 1, wherein a blank is molded which takes the form of a dome or the form of a cap with a lid portion and at least one side wall.

4. The method according to claim 1, wherein a raw material is provided which additionally contains particles without wavelength-converting properties.

5. The method according to claim 4, wherein the particles without wavelength-converting properties comprise aluminium oxide, aluminium nitride, boron nitride, titanium dioxide, zirconium dioxide and/or silicon dioxide.

6. The method according to claim 4, wherein the particles without wavelength-converting properties have a median grain diameter of less than or equal to 1 μm.

7. The method according to claim 1, wherein the luminescent material particles in the raw material have a median grain diameter of less than or equal to 5 μm, in particular of less than or equal to 1 μm.

8. The method according to claim 1, wherein the binder material contains an acrylate, a polyolefin, a polyol and/or silicone.

9. The method according to claim 1, wherein the binder material is removed by means of a solvent, by means of catalytic decomposition and/or by means of thermal decomposition.

10. A luminescence conversion element, in particular for an optoelectronic component, wherein the luminescence conversion element comprises a ceramic material containing luminescent material particles, which are bonded together and/or with further particles to yield the ceramic material.

11. The luminescence conversion element according to claim 10, which contains luminescent material particles and further particles, which are bonded to yield the ceramic material, wherein the further particles comprise aluminium oxide, aluminium nitride, boron nitride, titanium dioxide, zirconium dioxide and/or silicon dioxide.

12. The luminescence conversion element according to claim 11, wherein the further particles have a median grain diameter of less than or equal to 1 μm, and the luminescent material particles have a median grain diameter of less than or equal to 5 μm.

13. The luminescence conversion element according to claim 10, wherein at least one subregion takes the form of a lens and/or exhibits the shape of a cap with a lid portion and at least one side wall or the shape of a dome.

14. An optoelectronic component having a radiation-emitting semiconductor chip and a luminescence conversion element according to claim 10, which is adapted for wavelength conversion of least part of the electromagnetic radiation emitted by the semiconductor chip.

15. The optoelectronic component having a radiation-emitting semiconductor chip and a luminescence conversion element according to claim 14, which takes the shape of a cap and is intended for wavelength conversion of least part of the electromagnetic radiation emitted by the semiconductor chip, wherein the semiconductor chip is arranged at least partially in the cap.

16. The method according to claim 4, wherein the particles without wavelength-converting properties have a median grain diameter of less than or equal to 1 μm.

17. The method according to claim 1, wherein the luminescent material particles in the raw material have a median grain diameter of less than or equal to 5 μl, in particular of less than or equal to 1 μm.

18. The luminescence conversion element according to claim 11, wherein the further particles have a median grain diameter of less than or equal to 1 μM, and the luminescent material particles have a median grain diameter of less than or equal to 5 μm.
